(19) United States
(12) Patent Application Publication
(10) Pub. No.: US 2008/0100311 A1
(43) Pub. Date: May 1, 2008

(54) Electrical Measurement Of The Thickness Of A Semiconductor Layer

(75) Inventors: Karlheinz Freywald, Erfurt (DE); Giesbert Hoelzer, Erfurt (DE); Siegfried Hering, Kerspleben (DE); Uta Kuniss, Elleben (DE); Appo Van Der Wiel, Tervuren (BE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-FAB Semiconductor Foundries AG, Erfurt (DE)

(21) Appl. No.: 11/576,639

(22) PCT Filed: Nov. 16, 2005
(86) PCT No.: PCT/DE05/02063

§ 371 Date: Nov. 26, 2007

(30) Foreign Application Priority Data
Nov. 16, 2004 (DE) 10 2004 055 181.2

(51) Int. Cl. G01B 7/06; G01R 27/04; G01R 27/14

(52) U.S. Cl. 324/716

(57) ABSTRACT

A method for the electrical measurement of the thickness of a semiconductor layer ( 10, 11, 12) is disclosed. Active layers on SOI wafers, EPI layers with inverse conductivity tape and membrane thickness can be measured by use of a test structure which can routinely be measured during a production process. The embodiment of the test structure (A1 to F1) is preferably annular, such that a high degree of symmetry is achieved on propagation of the measuring current and such that no interactions occur with surrounding structures. The diameter of the arrangement can be matched to the corresponding thickness range of the semiconductor layer to be measured using conventional U-I parameter test systems, conventionally applied in semiconductor production. The determination of the layer thickness is achieved by means of two sequential quadrupole measurements at six contact points.

The invention relates to a method for the electrical measurement of the thickness of semiconductor layers and an arrangement associated therewith, which may be used as a test structure that is or may be fabricated during the standard device process of semiconductor structures by using conventional test systems. The arrangement formed as a test structure, for instance in an annular configuration, enables a reliable measurement and the suppression of interfering interactions with neighbouring structures.

The measurement techniques used so far do not meet the requirements with respect to a simple and reliable routine measurement within the electrical process control as an automatic measurement during the ongoing manufacturing process flow.

Conventional electrical methods are based on a 4-point measurement for determining the specific resistance of the semiconductor layer and are based on the measurement of the propagation resistance by two probe tips. From this the sheet resistance and the layer thickness may be calculated. The approach disclosed in JP-A 57 037 846 uses this combination of the two measurement techniques with a 4-probe tip arrangement, which contacts the semiconductor layer to be measured during the time of measurement by means of measurement tips. This method is a process usable in a laboratory but is not appropriate for routine operation in production.

JP-A 10 154 735 discloses a special method for measuring thin SOI layers by silicided areas. The method requires specific technological steps and may not be used in a general manner and is not provided or appropriate for semiconductor layers of increased thickness and for epi layers and membranes.

Further possibilities for thickness measurements of layers in semiconductors reside in the usage of other physical active principles, which are typically not available as routine techniques during the semiconductor production process and which would cause additional costs for the semiconductor production. In this respect the following citations may be mentioned, which, however, are not related to an electrically measuring method in a substantial manner.
Using X-rays and taking advantage of X-ray diffraction, for instance JP-A 10 185 537.
Exploiting the X-ray transmission, e.g., U.S. Pat. No. 6,434,217
Exploiting X-ray fluorescence, e.g., GB-A 2 323 164 and
Using interferometry, e.g., JP-A 2003 065 724, JP-A 06 077 302 and US-A 2003/218 758.
Application of ultra sonic, e.g., DE-B 44 14 030.

It is the purpose of the present invention to realize a measurement method for determining the thickness of semiconductor layers during the semiconductor production process by using automatic test systems. The method should be applicable in a general manner, for instance for the thickness measurement of active semiconductor layers on, e.g., SOI wafers, of epi (epitaxial) layers of inverse conductivity type and for the measurement of a membrane thickness.

It is an object of the present invention to provide an electrical method for measuring the thickness of semiconductor layers, wherein the measurement contacting is accomplished by a commonly used probe card, since usual test systems detect electrical measurement values only. For the reason of space saving an electrical isolation of other test elements located in the neighbourhood is desirable. In this case it is of great importance to find a solution without additional technological steps for realizing the test structure.

The object is solved by the features defined in claims 1 and 6.

Claims 1 and 6 provide the advantages that for the fabrication of the contacts on the semiconductor layer that are required for the application of the method no additional process steps are necessary and the specific test structure may be used in a test field for the measurement of parameters by means of automatic test systems. Moreover, only 6 contacts instead of 8 contacts are necessary for two required quadrupole measurements. The six contact regions are, however, positioned side by side, but they are also convoluted with each other.

The invention will be explained and completed by means of embodiments while using the drawings, in which

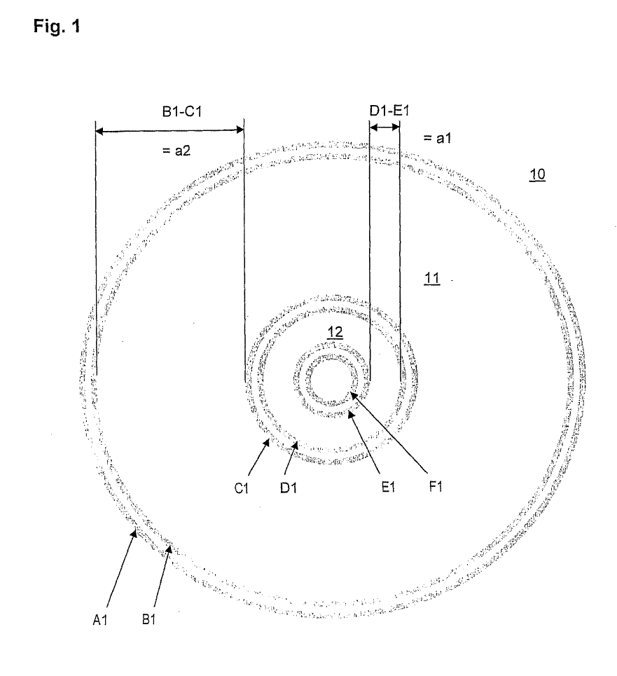

FIG. 1 is a schematic illustration of an annular arrangement of six contact regions A1 to F1 having a circular shape and being positioned within each other;

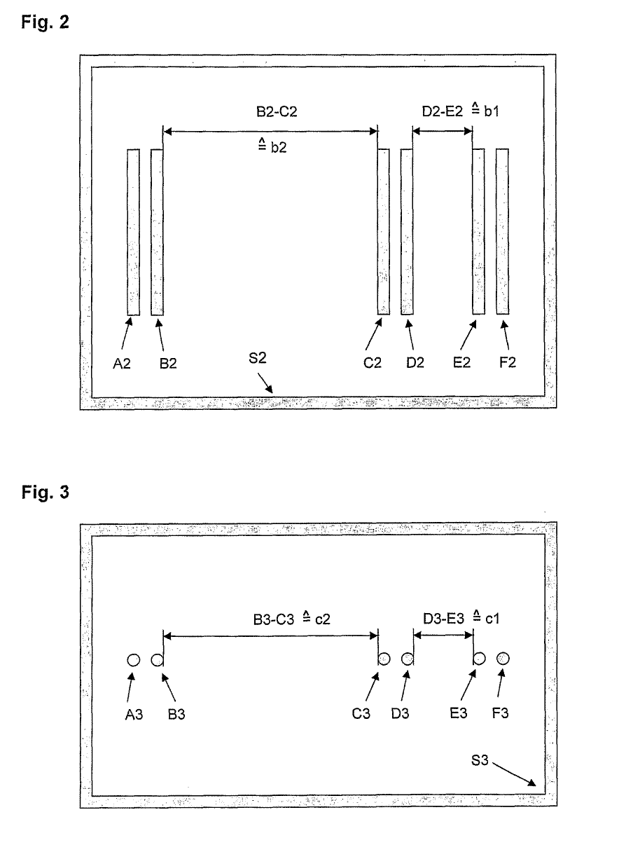

FIG. 2 is a schematic illustration of a linear arrangement including six rectilinear contact strips A2 to F2 and a surrounding protective frame S2;

FIG. 3 is a schematic illustration of point-like arrangement including six contact points A3 to F3 positioned in a line and a surrounding protective frame S3.

In FIG. 1 the six annular preferably metallic contact regions A1 to F1 are concentric to each other. They are located on the surface of a semiconductor layer 10, 11, 12.

During a measurement the two contact regions C1 and D1 positioned “in the centre” are each used twice, first, for applying the measurement current and second, for potential measurement. The measurement distances of the two measurements to be performed sequentially are B1-C1 and D1-E1. The same conditions are valid for the contact regions in FIG. 2 and FIG. 3. The protective areas (=frames) surrounding the test field are denoted as S2 and S3, for example, as a ring or a rectangle in the sense of a frame.

The index “i” used in the following relates to the contact regions in three described different contact arrangements on the surface and varies for the regions A to F with respect to three different arrangements of the contact regions.

All of the three different arrangements (contact region geometries or arrangements) have the common feature that the distances between Ai and Bi, Ci and Di, Ei and Fi are always minimal. However, the distance between the contacts Bi and Ci is the greater distance compared to the smaller distance Di and Ei. Di and Ei are positioned “in the centre”, that is, between the region pair Ai, Bi, on the one hand, and Ei, Fi, on the other hand.

The wiring of the individual contact regions is the same for each of the three arrangements. The respective measurements tips for current and voltage are not specifically illustrated, but will be appreciated by the skilled person without an illustration.

For the quadrupole measurement at the greater distance Bi-Ci the current injection (by means of tips) is accomplished at Ai and Di, while the potential drop caused by the current flow is measured (also by means of tips) across Bi and Ci. For the quadrupole measurement at the smaller distance Di-Ei the current is injected between Ci and Fi, while the potential difference is measured between Di and Ei, also using tips (measurement tips).

For electrical shielding with respect to other test elements in the vicinity a frame S2, S3 is provided for the respective test structure. The 6 contact regions of the double quadrupole arrangement may be embodied as a metal-semiconductor contact or as a diffusion region having as high a conductivity as possible that is then also connected via metal contacts.

The geometric arrangement of the six contact regions may preferably be annular and in this case an additional shielding is not required, as shown in FIG. 1.

A corresponding method for the electrical measurement of the thickness of a semiconductor layer 10, 11, 12 by means of the two convoluted quadrupole arrangements is accomplished in two steps. During the one measurement of the structure having the greater distance the measurement result is substantially determined by the sheet resistance of the semiconductor layer 11 to be measured. On the other hand, during the other measurement of the quadrupole arrangement having the smaller contact distance preferable the specific resistance of the semiconductor layer 12 to measured is determined. This may be referred to as first/second measurements, without indicating a specific order. The second measurement may as well be performed first.

Depending on the layer thickness of the semiconductor layer (10, 11, 12 form the same layer comprising different area-like sections) to be measured, the distances of the quadrupole arrangements may be adapted so as to achieve a resolution as high as possible, thereby resulting a high measurement accuracy within the range of layer thicknesses under consideration. Since both measurements include the influence of both parameters, the influence of the sheet resistance (and thus of the layer thickness) and the respective influence of the specific resistance, known interrelations of a complex mathematical relation that includes the geometry factors may be used for the evaluation. For this reason a mathematical modelling of the actual geometry makes sense and associated therewith a non-recurring calibration of at least two points for the further model adaption is performed.

The method for measuring the two quadrupole arrangements may likewise be applied to at least three types of contact regions, which are here illustrated as annular arrangement in the form of six circular-shaped concentric contact regions, six rectilinear parallel contact strips and six point-like contacts arranged in a line.

### REFERENCE SIGNS

A1: outer contact ring
B1: first inner contact ring
B1-C1: greater distance a2
C1: second inner contact ring
D1: third inner contact ring
D1-E1: smaller distance a1
E1: fourth inner contact ring
F1: fifth inner contact ring
A2: outer contact strip, one side
B2: first inner contact
B2-C2: greater distance; measurement distance b2
C2: second inner contact
D2: third inner contact
D2-E2: smaller distance; measurement distance b1
E2: fourth inner contact
F2: outer contact strip, other side
S2: protection ring
A3: outer contact point, one side
B3: first inner contact point
B3-C3: greater distance; measurement distance c2
C3: second inner contact point
D3: third inner contact point
D3-E3: smaller distance; measurement distance c1
E3: fourth inner contact point
F3: outer contact point, other side
S3: protection ring

We claim:

1. A method for electrical measurement of a thickness of a semiconductor layer by contacting contact regions formed on a surface of the semiconductor layer via measurement tips, said tips and regions being associated with a test structure and defining two geometrically different quadrupole arrangements positioned side by side, said quadrupole arrangements in particular being convoluted with each other; wherein
(a) the measurement comprises two subsequent “quadrupole measurements”, wherein the distance of the contact regions (b1, b2; a1, a2) with respect to each other is different during the two quadrupole measurements;
(b) the test structure in total comprises six contact regions (Ai to Fi, wherein i=1 . . . 3), of which two contact regions (C1, D1) located in the centre or between the other contact regions are doubly used such that these two contact regions, on the one hand, belong to the first quadrupole arrangement (A1 to D1) and, on the other hand, belong to the second quadrupole arrangement (C1 to F1), and wherein
(c1) during the one measurement of the quadrupole structure (quadrupole measurement) with a greater contact distance (a2) a first measurement value is measured that is mainly determined by the sheet resistance of the semiconductor layer to be measured;
(c2) during the second measurement of the quadrupole structure with a smaller contact distance (a1) a specific resistance of the semiconductor layer to be measured is mainly measured or determined;
(d) wherein the distances of the quadrupole arrangements are adapted to the layer thickness of the semiconductor layer to be measured so as to achieve a resolution as high as possible and thus obtain a high measurement accuracy within the range of layer thickness that is under consideration or accommodated by the measurement;
(e) wherein the layer thickness is calculated by means of a computational relation that includes the geometry factors.

2. The method of claim 1, wherein with respect to the computational (mathematical) relation a modelling is performed for an actual geometry and wherein a one-time calibration of at least two points for a further model adaptation is performed.

3. The method of claim 1, wherein one or more active semiconductor layers of an SOI wafer are measured.

4. The method of claim 1, wherein an epitaxial layer iof inverse conductivity type is measured as the semiconductor layer.

5. The method of claim 1, wherein a thickness of a membrane is measured as the semiconductor layer.

6. A geometry of contact regions for electrical measurement of a thickness of a semiconductor layer by contacting the contact regions (Ai, Bi, Ci, Di) on a surface of the semiconductor layer (10, 11, 12) by means of measurements tips, said tips belonging to a test structure and defining two geometrically different quadrupole arrangements arranged side by side,
characterized in that
the arrangement consists of two geometrically different quadrupole arrangements arranged side by side, wherein the distance of the contact regions to each other is different in the two quadrupole arrangements, the test structure in total comprises six contact regions, of which two contact regions located in the centre are doubly usable so as to use these doubly usable contact regions (C1, D1), on the one hand, together with the first quadrupole arrangement and, on the other hand, together with the second quadrupole arrangement, and wherein in the one quadrupole arrangement a greater distance (a2) of contact regions is provided to primarily determine the first measurement value by sheet resistance of the semiconductor layer to be measured and wherein in the second quadrupole arrangement a smaller distance (a1) is provided to determine the second measurement value from the specific resistance of the semiconductor layer (10, 11, 12) to be measured.

7. The arrangement of claim 6, wherein the distances of the quadrupole arrangements are adapted to the layer thickness of the semiconductor layer to be measured to achieve as high a resolution as possible and thus a high measurement accuracy within the range of layer thickness under consideration.

8. The arrangement of claims 6 or 7, wherein the six electrical contact regions (A1 to F1) of the double quadrupole arrangement are arranged concentrically within each other and concurrently form a shielding with respect to neighbouring test elelements.

9. The arrangement of claims 6 or 7, wherein the six electrical contact regions (A2 to F2) of the double quadrupole arrangement are arranged in parallel to each other in a strip-like manner and are surrounded by a protective frame (S2).

10. The arrangement of claims 6 or 7, wherein the six electrical contact regions (A3 to F3) of the double quadrupole arrangement are arranged in a point-like manner and are surrounded by a protective frame (S3).

11. The arrangement of claims 6 or 7 and of any of claims 8 to 10, wherein the six electrical contact regions of the double quadrupole arrangement are provided as direct metal-semiconductor contacts.

12. The arrangement of claims 6 or 7 and of any of claims 8 to 10, wherein the six electrical contact regions of the double quadrupole arrangement are provided as highly doped diffusion region that are contacted at defined positions by a metal.

13. The arrangement of claims 6 or 7 and of any of claims 8 to 10, wherein the six electrical contact regions of the double quadrupole arrangement are parts of a greater test field.

14. The method of claim 1, wherein the computational relation is a complex mathematical relation.

15. The arrangement of any of the preceding claims, wherein no more than six contact regions (A to F) are used for the measurement or a provided for the measurement.
